(19) United States
(12) Patent Application Publication
(10) Pub. No.: US 2024/0186594 A1
(43) Pub. Date: Jun. 6, 2024

(54) APPARATUSES AND METHODS FOR ELECTROCHEMICAL IMPEDANCE SPECTROSCOPY IN A RECONFIGURABLE BATTERY

(71) Applicant: Analog Devices International Unlimited Company, Limerick (IE)

(72) Inventor: Uwe BROECKELMANN, Issing (DE)

(21) Appl. No.: 18/463,060

(22) Filed: Sep. 7, 2023

Related U.S. Application Data
(60) Provisional application No. 63/576,434, filed on Dec. 6, 2022.

(51) Int. Cl. H01M 10/42; G01R 31/389; H01M 10/48

(52) U.S. Cl. CPC H01M 10/425; G01R 31/389; H01M 10/482

(57) ABSTRACT

Aspects of the present disclosure include a reconfigurable battery system having one or more battery clusters each having one or more switching devices and one or more battery cells, and an integrated controller configured to: transmit, from the integrated controller to the one or more switching devices associated with the one or more battery cells, one or more signals to generate a time-varying output current having a waveform, measure a time-varying voltage in response to the time-varying output current being applied to a load, and calculate an impedance based on the time-varying output current and the time-varying voltage at the frequency.

### CROSS-REFERENCE TO RELATED APPLICATIONS

The present application claims priority to, and the benefit of, U.S. Provisional Application No. 63/576,434, filed Dec. 8, 2022 and entitled “APPARATUSES AND METHODS FOR ELECTROCHEMICAL IMPEDANCE SPECTROSCOPY IN A RECONFIGURABLE BATTERY,” the contents of which are hereby incorporated by reference in their entireties.

### BACKGROUND

In many applications, such as automotive, reconfigurable batteries may be used to provide electrical power. Applications using the reconfigurable batteries may include electrical vehicles, energy storage systems, etc. Reconfigurable battery systems may include battery cells (or clusters of multiple cells) that can be dynamically connected/reconnected, and/or have their polarity/orientation changed. In reconfigurable battery systems, it may be important to monitor the “health” (i.e., battery condition, wear and tear, etc.) and “status” (i.e., cell temperature, state of charge, etc.) of individual reconfigurable cells within the systems. However, conventional monitoring systems may be costly and/or have limited visibility of key battery cell parameters. Therefore, improvements are desirable.

### SUMMARY

The following presents a simplified summary of one or more aspects in order to provide a basic understanding of such aspects. This summary is not an extensive overview of all contemplated aspects, and is intended to neither identify key or critical elements of all aspects nor delineate the scope of any or all aspects. Its sole purpose is to present some concepts of one or more aspects in a simplified form as a prelude to the more detailed description that is presented later.

Aspects of the present disclosure include a method including transmitting, from an integrated controller to one or more switching devices associated with one or more battery cells, one or more signals to generate a time-varying output current having a waveform, measuring a time-varying voltage in response to the time-varying output current being applied to a load, and calculating an impedance based on the time-varying output current and the time-varying voltage at the frequency.

Aspects of the present disclosure include a reconfigurable battery system having one or more battery clusters each having one or more switching devices and one or more battery cells, and an integrated controller configured to: transmit, from the integrated controller to the one or more switching devices associated with the one or more battery cells, one or more signals to generate a time-varying output current having a waveform, measure a time-varying voltage in response to the time-varying output current being applied to a load, and calculate an impedance based on the time-varying output current and the time-varying voltage at the frequency

To the accomplishment of the foregoing and related ends, the one or more aspects comprise the features hereinafter fully described and particularly pointed out in the claims. The following description and the annexed drawings set forth in detail certain illustrative features of the one or more aspects. These features are indicative, however, of but a few of the various ways in which the principles of various aspects may be employed, and this description is intended to include all such aspects and their equivalents.

### BRIEF DESCRIPTION OF THE DRAWINGS

The disclosed aspects will hereinafter be described in conjunction with the appended drawings, provided to illustrate and not to limit the disclosed aspects, wherein like designations denote like elements, and in which:

FIG. 1 illustrates an example of a unipolar reconfigurable battery system according to some aspects of the present disclosure.

FIG. 2 illustrates an example of a bipolar reconfigurable battery system according to some aspects of the present disclosure.

FIG. 3 illustrates an example of a reconfigurable battery system having a pulse width modulator according to some aspects of the present disclosure.

FIG. 4 illustrate examples of waveforms generated by the reconfigurable battery system according to some aspects of the present disclosure.

FIG. 5 illustrates an example of a scheme for discharging charges in a reconfigurable battery system according to some aspects of the present disclosure.

FIG. 6 illustrates an example of a pulse with modulation scheme in a unipolar reconfigurable battery system according to some aspects of the present disclosure.

FIG. 7 illustrates an example of a controller according to some aspects of the present disclosure.

FIG. 8 illustrates an example of a method for performing electrochemical impedance spectroscopy (EIS) in a reconfigurable battery system according to some aspects of the present disclosure.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known structures and components are shown in block diagram form in order to avoid obscuring such concepts.

An aspect of the present disclosure includes utilizing integrated switches (e.g., metal-oxide-semiconductor field-effect transistor (MOSFET) switches, metal-semiconductor field-effect transistor (MESFET) switches, bipolar junction transistor (BJT) switches, junction gate field-effect transistor (JFET) switches, etc.) in reconfigurable batteries to generate time-varying excitation currents/voltages for electrochemical impedance spectroscopy stimulus during various operational states without additional external circuitry. Aspects of the present disclosure may include the controllers for controlling the integrated switches as part of other functions applied during the various operations.

Electro-Impedance-Spectroscopy (EIS) is a scheme to detect variations of the impedance (i.e., resistance and/or reactance) of a battery cell as a function of frequency. A current may be supplied by the battery cell. A voltage is measured in response to the current being applied to a load. The impedance may be calculated based on the current and the voltage using Ohm's Law. The current may be applied at a particular frequency. As a result, the impedance may be calculated for the particular frequency.

Based on the impedance, certain information may be extracted such as temperature, state of charge, and/or state of health of the battery. The information may be used for diagnostics, improving performance, and/or design of the battery system. In one aspect, the EIS may be enabled by precisely synchronizing the voltage and/or the current reading of the battery cell at particular stimulus frequencies (e.g., between 100 millihertz (MHz) to 10 kilohertz (kHz)).

In some systems, a load current stimulus may be applied on the battery cell level via balancing transistors of the battery cell, on the module level via bypass circuitry, and/or on the pack level via modulating the existing system load (e.g., a battery heating system). For a sufficient signal to noise ratio, the stimulus current may be at least 1% of the battery rated maximum current, or applied for a longer time to allow filtering via averaging of the measurement results.

In some aspects of the present disclosure, to enable key-off (i.e., the vehicle is off) and key-on excitation in a synchronization of the voltage and current measurements inside a cluster with the frequency of the excitation current may be necessary. Various integrated circuit (IC) level implementations are possible. For example, one aspect of the present disclosure includes integrating an EIS engine (i.e., synchronized current/voltage reading) in a cell-monitoring IC, which may generate an excitation frequency signal to control the pulse width modulation (PWM) generation of the gate driver for a bridge (e.g., an H-Bridge) and/or the break/bypass switch, respectively. In another example, aspects of the present disclosure may include generating an excitation frequency signal in a central processing unit (CPU) synchronizing the voltage and/or current reading in the cell-monitoring IC and/or the gate driver. In yet another example, some aspects of the present disclosure include integrating cell monitoring and/or gate drive functions in a single IC with internal synchronization.

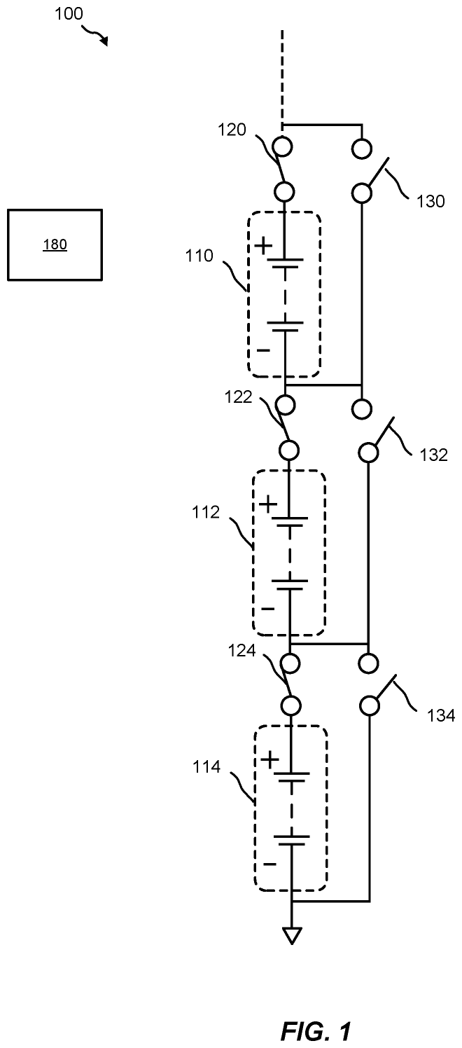

FIG. 1 illustrates an example of a unipolar reconfigurable battery system 100 according to aspects of the present disclosure. The unipolar reconfigurable battery system 100 may be configured to generate various levels of positive voltages based on a number of batteries electrically connected in series. The unipolar reconfigurable battery system 100 may include a first battery 110, a second battery 112, and a third battery 114. Other numbers of batteries may also be implemented according to aspects of the present disclosure. In some aspects, the unipolar reconfigurable battery system 100 may include a first switch 120 and a second switch 130 configured to provide a path for the first battery 110 to provide electrical energy or to bypass the first battery 110. The unipolar reconfigurable battery system 100 may include a third switch 122 and a fourth switch 132 configured to provide a path for the second battery 112 to provide electrical energy or to bypass the second battery 112. The unipolar reconfigurable battery system 100 may include a fifth switch 124 and a sixth switch 134 configured to provide a path for the third battery 114 to provide electrical energy or to bypass the third battery 114. The unipolar reconfigurable battery system 100 may include a controller 180 configured to control one or more of the first switch 120, the second switch 130, the third switch 122, the fourth switch 132, the fifth switch 124, and/or the sixth switch 134. The controller 180 may be an integrated controller built on the same chip as the switches 120, 130, 122, 132, 124, 134.

During operation, the controller 180 may open or close one or more switches, such as the first switch 120, the second switch 130, the third switch 122, the fourth switch 132, the fifth switch 124, and/or the sixth switch 134 to configure the number of batteries used for providing electrical energy from the unipolar reconfigurable battery system 100. For example, the controller 180 may cause the first switch 120, the third switch 122, and the fifth switch 124 to close, while causing the second switch 130, the fourth switch 132, and the sixth switch 134 to open, so the first battery 110, the second battery 112, and the third battery 114 are connected in series and collectively providing electrical energy (as shown in FIG. 1). As such, the output voltage of the unipolar reconfigurable battery system 100 may be the sum of the first battery 110, the second battery 112, and the third battery 114.

In a different example, the controller 180 may close the third switch 122, the second 130, and the sixth switch 134 and open the first switch 120, the fourth switch 132, and the fifth switch 124. Consequently, only the second battery 112 may output electrical energy from the unipolar reconfigurable battery system 100. Other configurations for the switches 120, 130, 122, 132, 124, 134 may be used to provide different amounts of electrical energy.

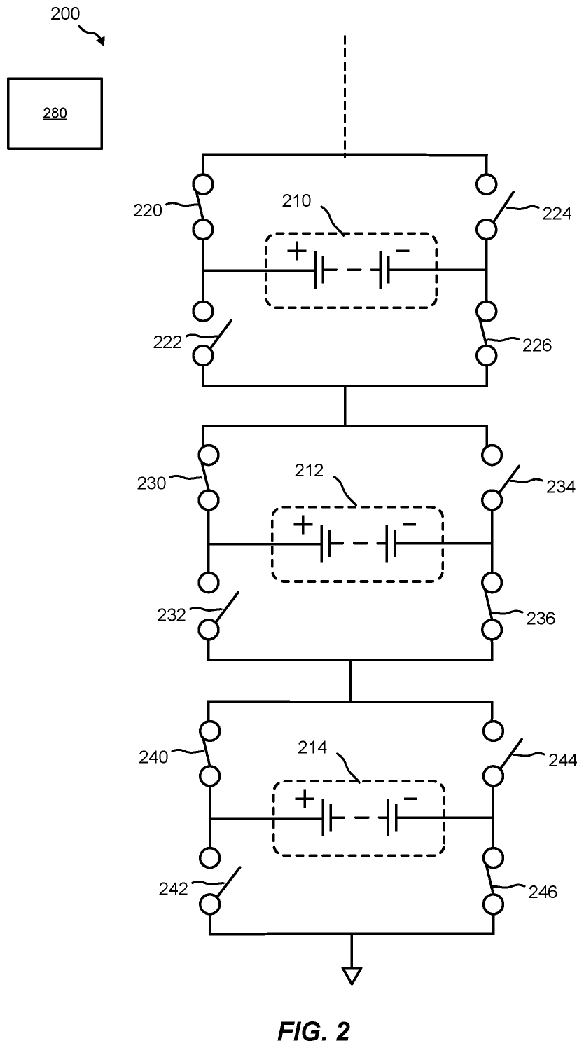

FIG. 2 illustrates an example of a bipolar reconfigurable battery system 200 according to aspects of the present disclosure. The bipolar reconfigurable battery system 200 may be configured to generate various levels of positive and/or negative voltages. The bipolar reconfigurable battery system 200 may include a first battery 210, a second battery 212, and a third battery 214. Other numbers of batteries and/or switches may also be implemented according to aspects of the present disclosure. The bipolar reconfigurable battery system 200 may include a first switch 220, a second switch 222, a third switch 224, and a fourth switch 226 in a bridge configuration around the first battery 210. The bipolar reconfigurable battery system 200 may include a fifth switch 230, a sixth switch 232, a seventh switch 234, and an eight switch 236 in a bridge configuration around the second battery 212. The bipolar reconfigurable battery system 200 may include a ninth switch 240, a tenth switch 242, an eleventh switch 244, and a twelfth switch 246 in a bridge configuration around the third battery 214.

In some aspects of the present disclosure, the bipolar reconfigurable battery system 200 may include a controller 280 configured to control one or more switches, such as the first switch 220, the second switch 222, the third switch 224, the fourth switch 226, the fifth switch 230, the sixth switch 232, the seventh switch 234, the eighth switch 236, the ninth switch 240, the tenth switch 242, the eleventh switch 244, and/or the twelfth switch 246. The controller 180 may be an integrated controller built on the same chip as the switches 220, 222, 224, 226, 230, 232, 234, 236, 240, 242, 244, 246.

During operation, the controller 280 may open or close one or more of the switches 220, 222, 224, 226, 230, 232, 234, 236, 240, 242, 244, 246 to configure the number of batteries used for providing electrical energy from the bipolar reconfigurable battery system 200. For example, the controller 280 may open the second switch 222, the third switch 224, the sixth switch 232, the seventh switch 234, the tenth switch 242, and the eleventh switch 244 and close the remaining switches so the first battery 210, the second battery 212, and the third battery 214 are connected in series and collectively providing electrical energy (as shown in FIG. 2). As such, the output voltage of the bipolar reconfigurable battery system 200 may be the sum of the first battery 210, the second battery 212, and the third battery 214. Further, the output voltage may be a positive voltage in the configuration shown.

Alternatively, the controller 280 may close the second switch 222, the third switch 224, the sixth switch 232, the seventh switch 234, the tenth switch 242, and the eleventh switch 244 and close the remaining switches so the first battery 210, the second battery 212, and the third battery 214 are connected in series and collectively providing electrical energy. As such, the output voltage of the bipolar reconfigurable battery system 200 may be the sum of the first battery 210, the second battery 212, and the third battery 214. However, in this configuration, the output voltage may be a negative voltage.

In other aspects of the present disclosure, the controller 280 may open and/or close one or more of the switches 220, 222, 224, 226, 230, 232, 234, 236, 240, 242, 244, 246 to provide different amounts of electrical energy from the bipolar reconfigurable battery system 200.

In certain aspects of the present disclosure, the bipolar reconfigurable battery system 200 may be used to synthesize alternating current (AC) voltage waveforms to drive AC motors, and/or coupled to the AC grid for charging or supply. In an AC battery system, three strings of cells or clusters may be used in a parallel setup to generate 120° out-of-phase sinusoidal waves. Other numbers of strings/clusters may also be used.

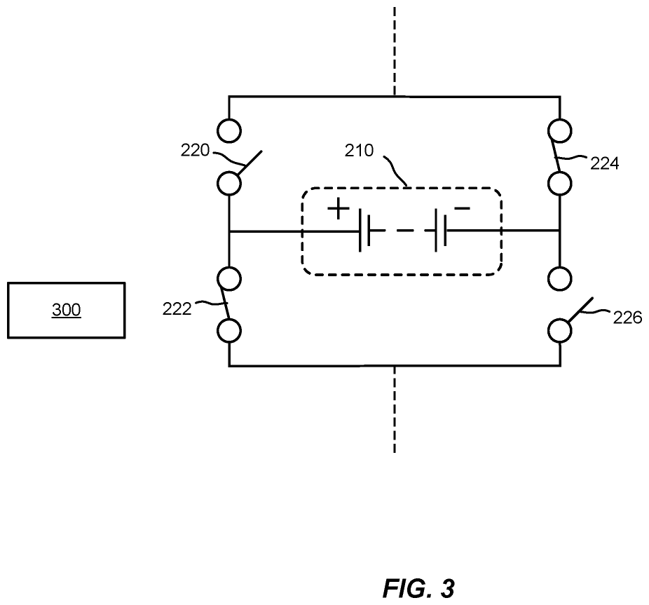

FIG. 3 illustrates an example of a battery cell having a pulse width modulator (PWM) 300 according to aspects of the present disclosure. In an AC battery system, battery clusters may be switched in and out to generate a time-varying waveform, such as a sinusoidal wave. If the battery clusters are switched in and out, a staircase waveform may be generated, where the step size equals to the cluster voltage. To smooth the waveform, the PWM 300 may be used when switching in the latest cluster joining the output waveform. This may be useful, for example, at low-speed driving and/or AC charging. In some aspects, the PWM 300 may be used to “smooth” the steps of an AC battery system. The PWM 300 may be used in the bipolar reconfigurable battery system 200 and/or the unipolar reconfigurable battery system 100. For example, the PWM 300 may add resistance to the output current, and therefore, the time-varying waveform.

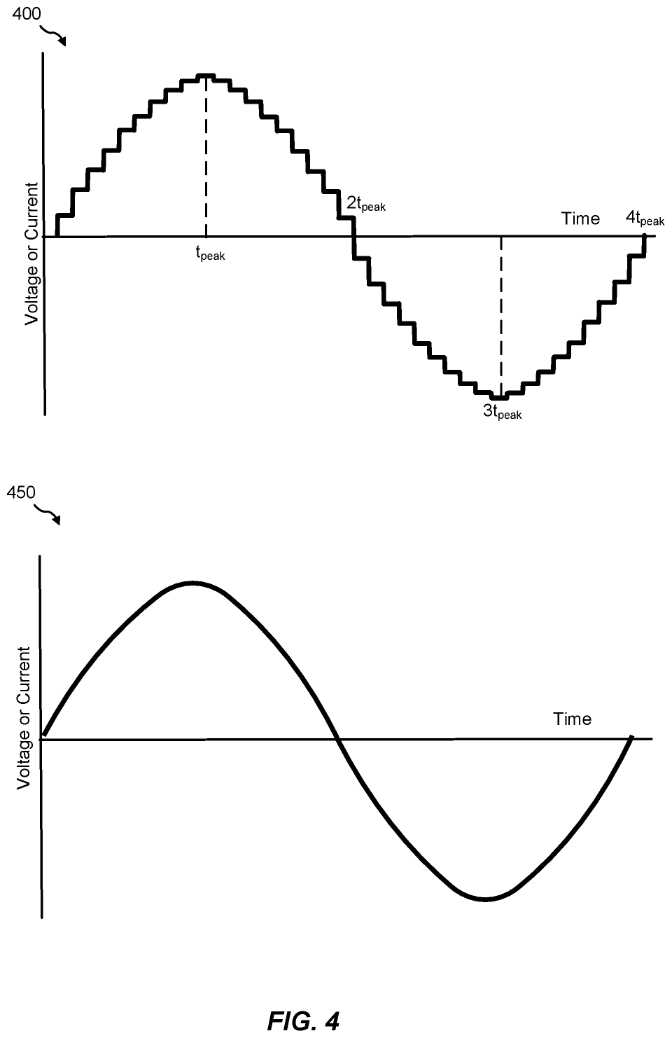

FIG. 4 illustrates examples of output voltage/current behaviors of a battery cluster. In a first graph 400, a controller of a battery cluster may progressively activate/deactivate battery cells within the cluster to produce a step-wise sinusoidal wave shown in the first graph 400. For example, the controller of the battery cluster may activate one battery cell at a first time, two battery cells at a second time . . . and all the battery cells at a time tₚₑₐₖ. Subsequently, the controller of the battery cluster may deactivate one battery cell at a first time after tₚₑₐₖ, two battery cells at a second time after tₚₑₐₖ . . . and all the battery cells at a time 2tₚₑₐₖ. After 2tₚₑₐₖ, the controller of the battery cluster may activate one battery cell (with polarity flipped) at a first time after 2tₚₑₐₖ, two battery cells (with polarity flipped) at a second time after 2tₚₑₐₖ . . . and all the battery cells (with polarity flipped) at a time 3tₚₑₐₖ. After 3tₚₑₐₖ, the controller of the battery cluster may deactivate one battery cell (with polarity flipped) at a first time after 3tₚₑₐₖ, two battery cells (with polarity flipped) at a second time after 3tₚₑₐₖ . . . and all the battery cells at a time 4tₚₑₐₖ. The progressive activation and deactivation of the battery cells in the battery cluster may produce a step-wise sinusoidal wave shown in the first graph 400.

In some aspects of the present disclosure, in a second graph 450, the controller of the battery cluster may utilize one or more PWMs to produce the sinusoidal wave shown.

In certain aspects of the present disclosure, the step-wise sinusoidal wave shown in the first graph 400 or the sinusoidal wave shown in the second graph 450 may represent the stimulus current (or voltage) output by the battery cluster. The battery cluster, such as the unipolar reconfigurable battery system 100 and/or the bipolar reconfigurable battery system 200, may output one or more sinusoidal waves. The output sinusoidal waves may be applied to one or more loads (e.g., vehicle motor, lights, etc.) as part of the EIS excitation. The output sinusoidal (step-wise as shown in 400 or smooth as shown in 450) waves may be applied to one or more loads while the EIS analysis is performed to monitor the health of the battery. In one example, the EIS analysis based on the application of the output sinusoidal waves onto the one or more loads may be done when the vehicle is in the on state (i.e., key-on excitation).

In certain aspects of the present disclosure, the PWM switching techniques may be used for EIS excitation during drive mode at one or more clusters (e.g., the last cluster) adding to the output voltage, for example in regions where PWM mode would be option to smooth the output waveform and with higher excitation frequencies.

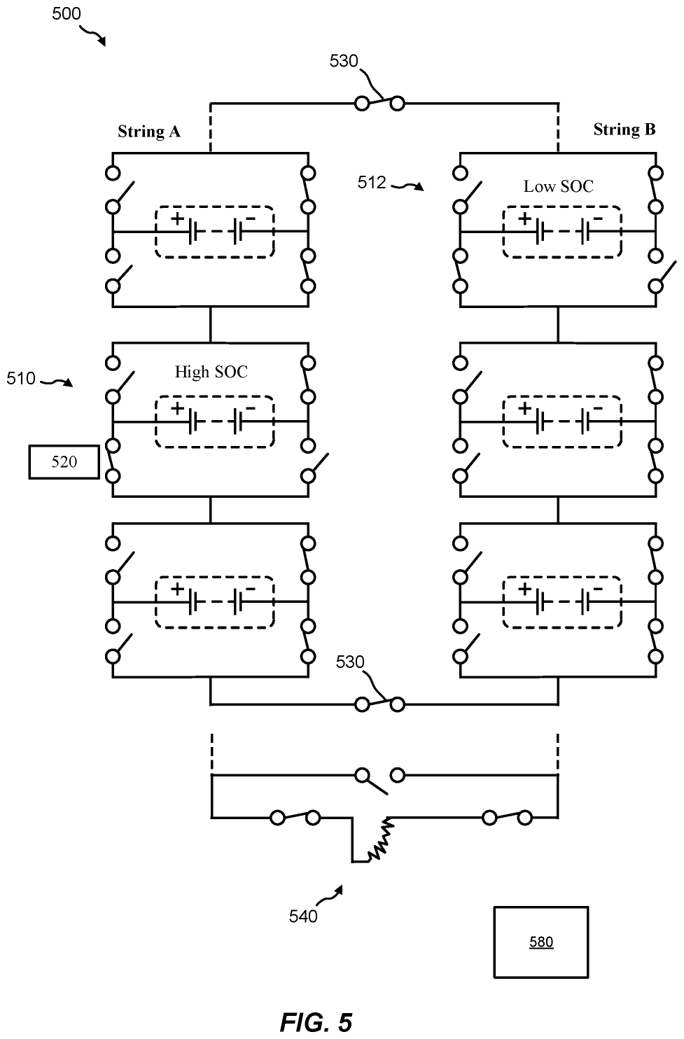

FIG. 5 illustrates an example of a reconfigurable battery system 500 according to aspects of the present disclosure. In some instances, the EIS analysis may be performed without at active load (e.g., the electric vehicle is off). As such, a battery cell with lower state of charge (SOC) may function as the load to another battery cell with higher SOC. An aspect of the present disclosure may include transferring charges from a cluster with higher SOC (e.g., higher voltage) to one with sufficiently lower SOC (lower voltage) to allow sufficient measurement time. In one instance, the cluster with higher SOC may be in a string and the cluster with lower SOC may be in a neighbor string. The position of the clusters in the string may be flexible, and the remaining clusters (aside from the two selected clusters), may be in bypass mode.

In some aspects, the stimulus frequency may be generated by a PWM signal in one of the bridge switches in the high SOC clusters. The excitation frequencies may correlate to the charge difference between the two clusters, and/or the usable measurement time. The current flow between the strings may be enabled by closing the contactors between the strings.

In certain aspects, if a higher discharge resistance is necessary, the current may be routed through one of the motor windings (i.e., which may not lead to any motor movement) to discharge the current.

During EIS measurements, active balancing requirements between clusters and/or strings may be used to select the combination of clusters as source and sink.

In some aspects of the present disclosure, the reconfigurable battery system 500 may include a String A and a String B. The String A may include a first cluster 510 having a higher SOC. The String B may include a second cluster 512 having a lower SOC. The first cluster 510 may include a PWM 520 configured to add resistance to control the discharge current flowing among cells and/or clusters. The reconfigurable battery system 500 may include one or more contactors 530. The reconfigurable battery system 500 may optionally include a load 540 (e.g., an electric motor). The reconfigurable battery system 500 may include a controller 580 configured to control the electrical energy supplied by one or more of the first cluster 510 or the second cluster 512, the PWM 520, and/or the one or more contactors 530. The controller 580 may be integrated with the onto the same silicon chip as the switches controlling the first cluster 510 and/or the second cluster 512, the PWM 520, and/or the one or more contactors 530.

During operation, the first cluster 510 may have a higher SOC than the second cluster 512. The controller 580 may activate some of the switches in the first cluster 510 and some of the switches of the second cluster 512 such that the first cluster 510 charges the second cluster 512. For example, the positive terminal of the battery in the first cluster 510 may connect to the positive terminal of the battery in the second cluster 512, while the negative terminal of the battery in the first cluster 510 may connect to the negative terminal of the battery in the second cluster 512. As such, the second cluster 512 may function as the load for the first cluster 510.

In some aspects of the present disclosure, during an EIS measurement, the controller 580 may close the one or more contactors 530 to electrically couple the String A and the String B. The controller 580 may close certain switches of one or more clusters in the String A and/or the String B to bypass the one or more clusters. The controller 580 may progressively open and close the switches in the first cluster 510 and the second cluster 512 such that the second cluster 512 receives an EIS stimulus current at a particular frequency, which may depend at least partially on the rate the controller 580 opens and closes the switches. The controller 580 may control the switches such that the first cluster 510, which has a higher SOC as indicated above, functions as a source and the second cluster 512, which has a lower SOC as indicated above, functions as a sink. In some aspects of the present disclosure, the controller 580 may synchronously control the switches of the first cluster 510 and the switches of the second cluster 512.

In some instances, the charges in the first cluster 510 may be provided to the load 540 (e.g., electrical motor winding).

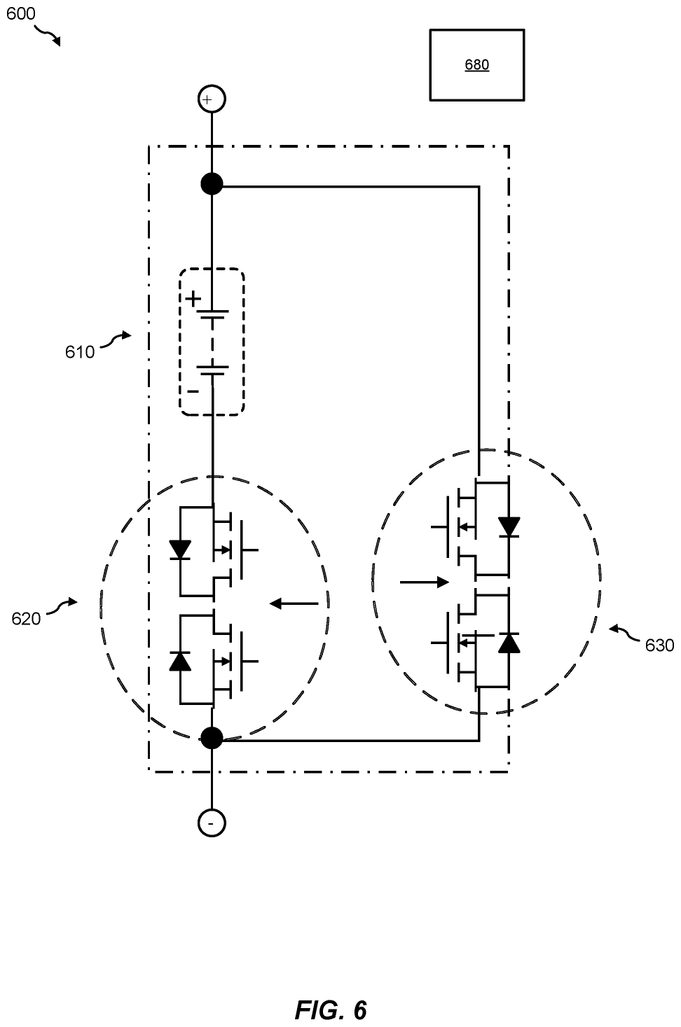

FIG. 6 illustrates another example of a reconfigurable battery system 600 according to aspects of the present disclosure. The reconfigurable battery system 600 may include one or more battery clusters 610 configured to provide electrical energy stored therein. The reconfigurable battery system 600 may include a break circuit 620 configured to connect and/or disconnect the one or more battery clusters 610 from the reconfigurable battery system 600. For example, the break circuit 620 may be activated to reduce the electrical energy output from the reconfigurable battery system 600 to allow soft switching. The reconfigurable battery system 600 may include a bypass switch 630 configured to provide a bypass connection. In some aspects of the present disclosure, the break circuit 620 may be activated to disconnect the one or more battery clusters 610 before the bypass switch 630 is closed to provide 0 A or 0 V output.

The reconfigurable battery system 600 may include a controller 680 configured to control the switches in the one or more battery clusters 610, the operations of the break circuit 620, and/or the operation of the bypass switch 630. The controller 680 may be integrated onto a single chip as one or more of the switches of the one or more battery clusters 610 and/or the break circuit 620.

During operation, in some aspects of the present disclosure, the controller 680 may activate the break circuit 620 and/or the bypass switch 630 to generate an variable load current. For example, by repurposing the break circuit 620, the reconfigurable battery system 600 may generate an excitation current with a waveform during partial load operation modes for EIS measurements. The output may be a DC voltage/current. The amplitude may be changed by adding or removing cells or clusters via the bypass switch 630 and/or the break circuit 620 for different voltage levels for traction and/or charging (e.g., 400V vs. 800V DC fast charging).

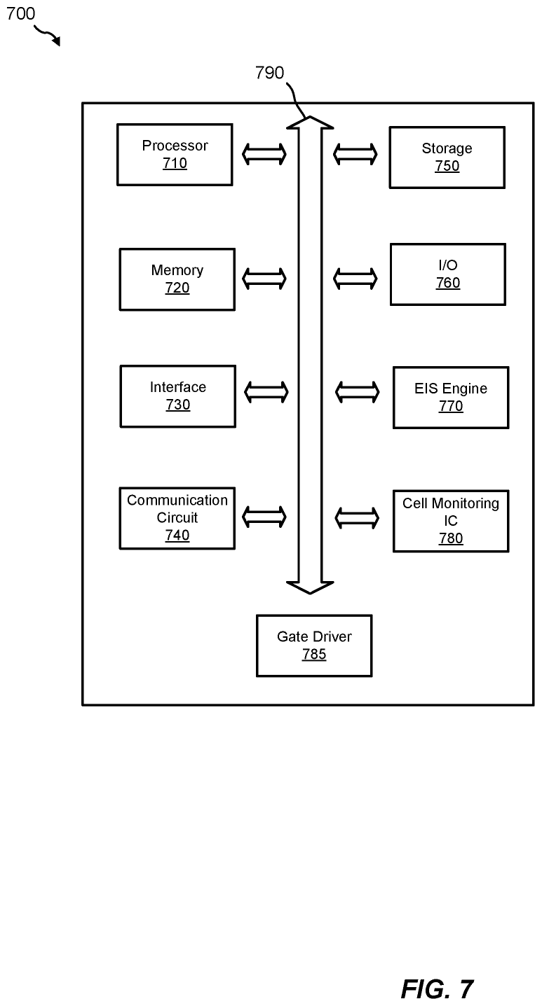

FIG. 7 illustrates an example of a controller 700 for a reconfigurable battery system. The controller 700 may include some or all of the functions of the controllers 180, 280, 580, 680. The controller 700 may be in a single package or as a chip set assembly with multiple components. The controller 700 may include a processor 710 configured to execute instructions stored in a memory 720. The memory 720 may include computer executable instructions. The controller 700 may include an interface circuit 730 configured to provide a hardware interface with external devices. The controller 700 may include a communication circuit 740 configured to communicate via wired or wireless communication channels. The controller 700 may include a storage 750 configured to store digital information. The controller 700 may include an input/output (I/O) interface device 760 configured to receive input signals and/or transmit output signals.

In some aspects of the present disclosure, the controller 700 may include an EIS engine 770 configured to perform EIS analysis. The controller 700 may include a cell monitoring IC 780 configured to monitor and/or analyze the battery systems described above. The controller 700 may include a gate driver 785 configured to drive the switches of the reconfigurable battery system. The gate driver 785 may be configured to receive the PWM signals to open and/or close the switches with the desired frequency. The controller 700 may include a bus 790 configured to provide connections among the subcomponents of the controller 700. The controllers 180, 280, 580, 680 may be implemented as the controller 700, and/or include one or more subcomponents of the controller 700.

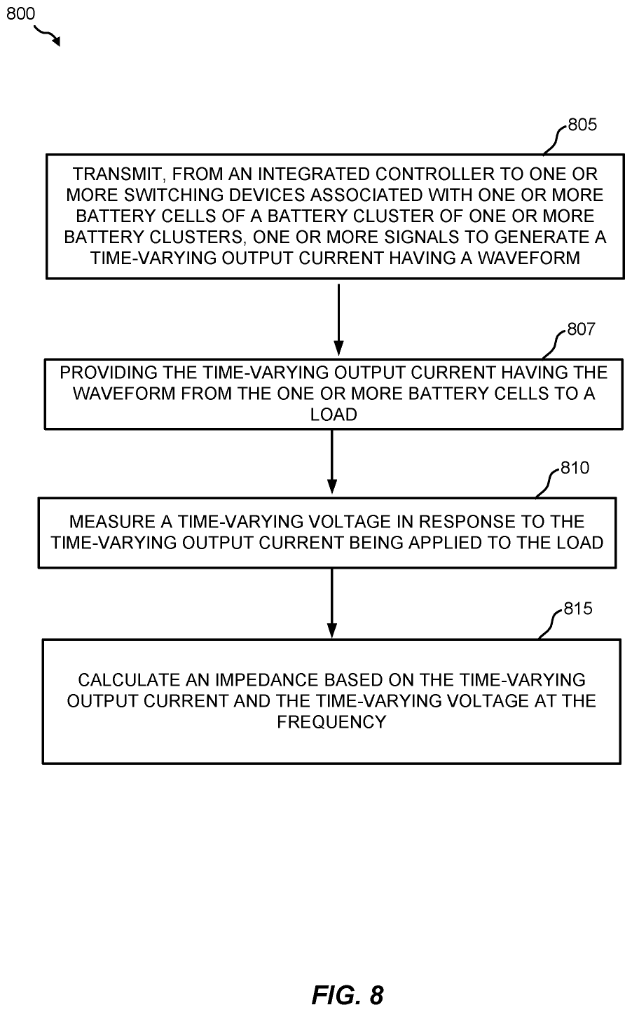

FIG. 8 illustrates a method 800 for performing an EIS analysis of a reconfigurable battery system. The method 800 may be performed by one or more of the controllers 180, 280, 580, 680, 700, and/or one or more subcomponents of the 180, 280, 580, 680, 700.

At 805, the method 800 may transmit, from an integrated controller to one or more switching devices associated with one or more battery cells of a battery cluster of one or more battery clusters, one or more signals to generate a time-varying output current having a waveform. For example, the controller 180, 280, 580, 680, 700 may be configured to, and/or provide the means for, transmitting, from an integrated controller to one or more switching devices associated with one or more battery cells of a battery cluster of one or more battery clusters, one or more signals to generate a time-varying output current having a waveform.

At 807, the method 800 may provide the time-varying output current having the waveform from the one or more battery cells to a load. For example, the reconfigurable battery system 100, the bipolar reconfigurable battery system 200, the reconfigurable battery system 500, and/or the reconfigurable battery system 600 may be configured to, and/or provide the means for, providing the time-varying output current having the waveform from the one or more battery cells to a load.

At 810, the method 800 may measure a time-varying voltage in response to the time-varying output current being applied to the load. For example, the controller 180, 280, 580, 680, 700 may be configured to, and/or provide the means for, measuring a time-varying voltage in response to the time-varying output current being applied to the load.

At 815, method 800 may calculate an impedance based on the time-varying output current and the time-varying voltage at the frequency. For example, the controller 180, 280, 580, 680, 700 may be configured to, and/or provide the means for, calculating an impedance based on the time-varying output current and the time-varying voltage at the frequency.

Aspects of the present disclosure include a method including transmitting, from an integrated controller to one or more switching devices associated with one or more battery cells, one or more signals to generate a time-varying output current having a waveform, measuring a time-varying voltage in response to the time-varying output current being applied to a load, and calculating an impedance based on the time-varying output current and the time-varying voltage at the frequency.

Aspects of the present disclosure include a reconfigurable battery system having one or more battery clusters each having one or more switching devices and one or more battery cells, and an integrated controller configured to: transmit, from the integrated controller to the one or more switching devices associated with the one or more battery cells, one or more signals to generate a time-varying output current having a waveform, measure a time-varying voltage in response to the time-varying output current being applied to a load, and calculate an impedance based on the time-varying output current and the time-varying voltage at the frequency.

Aspects of the present disclosure include the reconfigurable battery system above, wherein the one or more battery clusters are unipolar battery clusters.

Aspects of the present disclosure include any of the reconfigurable battery systems above, wherein the one or more switching devices are break and by-pass circuits.

Aspects of the present disclosure include any of the reconfigurable battery systems above, wherein the time-varying output current periodically fluctuates between a positive amplitude and zero.

Aspects of the present disclosure include any of the reconfigurable battery systems above, wherein the one or more battery clusters are bipolar battery clusters.

Aspects of the present disclosure include any of the reconfigurable battery systems above, wherein the one or more switching devices are switches arranged in an H-bridge around a corresponding battery cluster.

Aspects of the present disclosure include any of the reconfigurable battery systems above, wherein the time-varying output current periodically fluctuates between a positive amplitude, zero and a negative amplitude.

Aspects of the present disclosure include any of the reconfigurable battery systems above, wherein the integrated controller includes an electrochemical impedance spectroscopy (EIS) engine and a cell-monitoring integrated circuit (IC).

Aspects of the present disclosure include any of the reconfigurable battery systems above, wherein the integrated controller includes a central processing unit (CPU) configured to synchronize a voltage reading of the time-varying voltage and a current reading of the time-varying output current.

Aspects of the present disclosure include any of the reconfigurable battery systems above, wherein the integrated controller includes a cell-monitoring integrated circuit (IC) and one or more gate drivers.

The above detailed description set forth above in connection with the appended drawings describes examples and does not represent the only examples that may be implemented or that are within the scope of the claims. The term “example,” when used in this description, means “serving as an example, instance, or illustration,” and not “preferred” or “advantageous over other examples.” The detailed description includes specific details for the purpose of providing an understanding of the described techniques. These techniques, however, may be practiced without these specific details. For example, changes may be made in the function and arrangement of elements discussed without departing from the scope of the disclosure. Also, various examples may omit, substitute, or add various procedures or components as appropriate. For instance, the methods described may be performed in an order different from that described, and various steps may be added, omitted, or combined. Also, features described with respect to some examples may be combined in other examples. In some instances, well-known structures and apparatuses are shown in block diagram form in order to avoid obscuring the concepts of the described examples.

Information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, computer-executable code or instructions stored on a computer-readable medium, or any combination thereof.

Several aspects of telecommunication systems will now be presented with reference to various apparatus and methods. These apparatus and methods will be described in the following detailed description and illustrated in the accompanying drawings by various blocks, components, circuits, processes, algorithms, etc. (collectively referred to as “elements”). These elements may be implemented using electronic hardware, computer software, or any combination thereof. Whether such elements are implemented as hardware or software depends upon the particular application and design constraints imposed on the overall system.

By way of example, an element, or any portion of an element, or any combination of elements may be implemented as a “processing system” that includes one or more processors. Examples of processors include microprocessors, microcontrollers, graphics processing units (GPUs), central processing units (CPUs), application processors, digital signal processors (DSPs), reduced instruction set computing (RISC) processors, systems on a chip (SoC), baseband processors, field programmable gate arrays (FPGAs), programmable logic devices (PLDs), state machines, gated logic, discrete hardware circuits, and other suitable hardware configured to perform the various functionality described throughout this disclosure. One or more processors in the processing system may execute software. Software shall be construed broadly to mean instructions, instruction sets, code, code segments, program code, programs, subprograms, software components, applications, software applications, software packages, routines, subroutines, objects, executables, threads of execution, procedures, functions, etc., whether referred to as software, firmware, middleware, microcode, hardware description language, or otherwise.

Accordingly, in one or more example embodiments, the functions described may be implemented in hardware, software, or any combination thereof. If implemented in software, the functions may be stored on or encoded as one or more instructions or code on a computer-readable medium. Computer-readable media includes computer storage media. Storage media may be any available media that may be accessed by a computer. By way of example, and not limitation, such computer-readable media may comprise a random-access memory (RAM), a read-only memory (ROM), an electrically erasable programmable ROM (EEPROM), optical disk storage, magnetic disk storage, other magnetic storage devices, combinations of the aforementioned types of computer-readable media, or any other medium that may be used to store computer executable code in the form of instructions or data structures that may be accessed by a computer.

The various illustrative blocks and components described in connection with the disclosure herein may be implemented or performed with a specially-programmed device, such as but not limited to a processor, a digital signal processor (DSP), an ASIC, a FPGA or other programmable logic device, a discrete gate or transistor logic, a discrete hardware component, or any combination thereof designed to perform the functions described herein. A specially-programmed processor may be a microprocessor, but in the alternative, the processor may be any conventional processor, controller, microcontroller, or state machine. A specially-programmed processor may also be implemented as a combination of computing devices, e.g., a combination of a DSP and a microprocessor, multiple microprocessors, one or more microprocessors in conjunction with a DSP core, or any other such configuration.

The functions described herein may be implemented in hardware, software executed by a processor, firmware, or any combination thereof. If implemented in software executed by a processor, the functions may be stored on or transmitted over as one or more instructions or code on a non-transitory computer-readable medium. Other examples and implementations are within the scope and spirit of the disclosure and appended claims. For example, due to the nature of software, functions described above may be implemented using software executed by a specially programmed processor, hardware, firmware, hardwiring, or combinations of any of these. Features implementing functions may also be physically located at various positions, including being distributed such that portions of functions are implemented at different physical locations. Also, as used herein, including in the claims, “or” as used in a list of items prefaced by “at least one of” indicates a disjunctive list such that, for example, a list of “at least one of A, B, or C” means A or B or C or AB or AC or BC or ABC (i.e., A and B and C).

Computer-readable media includes both computer storage media and communication media including any medium that facilitates transfer of a computer program from one place to another. A storage medium may be any available medium that may be accessed by a general purpose or special purpose computer. By way of example, and not limitation, computer-readable media may comprise RAM, ROM, EEPROM, CD-ROM or other optical disk storage, magnetic disk storage or other magnetic storage devices, or any other medium that may be used to carry or store desired program code means in the form of instructions or data structures and that may be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, include compact disc (CD), laser disc, optical disc, digital versatile disc (DVD), floppy disk and Blu-ray disc where disks usually reproduce data magnetically, while discs reproduce data optically with lasers. Combinations of the above are also included within the scope of computer-readable media.

The previous description of the disclosure is provided to enable a person skilled in the art to make or use the disclosure. Various modifications to the disclosure will be readily apparent to those skilled in the art, and the common principles defined herein may be applied to other variations without departing from the spirit or scope of the disclosure. Furthermore, although elements of the described aspects may be described or claimed in the singular, the plural is contemplated unless limitation to the singular is explicitly stated. Additionally, all or a portion of any aspect may be utilized with all or a portion of any other aspect, unless stated otherwise. Thus, the disclosure is not to be limited to the examples and designs described herein but is to be accorded the widest scope consistent with the principles and novel features disclosed herein.

What is claimed is:

1. A reconfigurable battery system, comprising:
one or more battery clusters each having one or more switching devices and one or more battery cells; and
an integrated controller configured to:
transmit, from the integrated controller to the one or more switching devices associated with the one or more battery cells, one or more signals to generate a time-varying output current having a waveform;
measure a time-varying voltage in response to the time-varying output current being applied to a load; and
calculate an impedance based on the time-varying output current and the time-varying voltage at the frequency.

2. The reconfigurable battery system of claim 1, wherein the one or more battery clusters are unipolar battery clusters.

3. The reconfigurable battery system of claim 2, wherein the one or more switching devices are break and by-pass circuits.

4. The reconfigurable battery system of claim 2, wherein the time-varying output current periodically fluctuates between a positive amplitude and zero.

5. The reconfigurable battery system of claim 1, wherein the one or more battery clusters are bipolar battery clusters.

6. The reconfigurable battery system of claim 5, wherein the one or more switching devices are switches arranged in an H-bridge around a corresponding battery cluster.

7. The reconfigurable battery system of claim 5, wherein the time-varying output current periodically fluctuates between a positive amplitude, zero and a negative amplitude.

8. The reconfigurable battery system of claim 5, wherein the integrated controller includes an electrochemical impedance spectroscopy (EIS) engine and a cell-monitoring integrated circuit (IC).

9. The reconfigurable battery system of claim 5, wherein the integrated controller includes a central processing unit (CPU) configured to synchronize a voltage reading of the time-varying voltage and a current reading of the time-varying output current.

10. The reconfigurable battery system of claim 5, wherein the integrated controller includes a cell-monitoring integrated circuit (IC) and one or more gate drivers.

11. A method of operating a reconfigurable battery system, comprising:
transmitting, from an integrated controller to one or more switching devices associated with one or more battery cells of a battery cluster of one or more battery clusters, one or more signals to generate a time-varying output current having a waveform;
providing the time-varying output current having the waveform from the one or more battery cells to a load;
measuring a time-varying voltage in response to the time-varying output current being applied to the load; and
calculating an impedance based on the time-varying output current and the time-varying voltage at the frequency.

12. The method of claim 11, wherein the one or more battery clusters are unipolar battery clusters.

13. The method of claim 12, wherein the one or more switching devices are break and by-pass circuits.

14. The method of claim 12, wherein the time-varying output current periodically fluctuates between a positive amplitude and zero.

15. The method of claim 11, wherein the one or more battery cells are bipolar battery clusters.

16. The method of claim 15, wherein the one or more switching devices are switches arranged in an H-bridge around a corresponding battery cluster.

17. The method of claim 15, wherein the time-varying output current periodically fluctuates between a positive amplitude, zero and a negative amplitude.

18. The method of claim 15, wherein the integrated controller includes an electrochemical impedance spectroscopy (EIS) engine and a cell-monitoring integrated circuit (IC).

19. The method of claim 15, wherein the integrated controller includes a central processing unit (CPU) configured to synchronize a voltage reading of the time-varying voltage and a current reading of the time-varying output current.

20. The method of claim 15, wherein the integrated controller includes a cell-monitoring integrated circuit (IC) and one or more gate drivers.
